(19) United States
(12) Patent Application Publication
(10) Pub. No.: US 2010/0044552 A1
(43) Pub. Date: Feb. 25, 2010

(54) AUTOMATIC SIMULTANEOUS DUAL GAIN READOUT INTEGRATED CIRCUIT USING THRESHOLD VOLTAGE SHIFTS OF MOSFET BULK TO SOURCE POTENTIAL

(75) Inventor: Bryan J. CHEN, Santa Barbara, CA (US)

Correspondence Address: MCDERMOTT WILL & EMERY LLP, 18191 VON KARMAN AVE., SUITE 500, IRVINE, CA, 92612-7108, US

(73) Assignee: Lockheed Martin Corporation, Bethesda, MD (US)

(21) Appl. No.: 12/194,505

(22) Filed: Aug. 19, 2008

(51) Int. Cl. H01L 27/00; H03F 3/08

(52) U.S. Cl. 250/208.1; 250/214 A

(57) ABSTRACT

The present disclosure is directed to automatic gain switching circuits for implementation with photodetectors that include a switchable storage network including a storage element. The switchable storage network, such as one or more capacitors, is configured and arranged to respond to a photocurrent from the photodetector and provide an increased storage for the circuit at a predetermined photocurrent. The storage elements can include one or more capacitors that can be coupled to integration capacitors of the photodetector. The switchable networks can include flux sensing switches such as MOSFETS that can activate at a desired or predetermined photocurrent level. Related methods of providing multiple gain values for a photodetector circuit, as well as focal plane arrays and imaging systems with automatic gain shifting are also described.

### STATEMENT REGARDING FEDERALLY SPONSORED RESEARCH OR DEVELOPMENT

Not applicable.

### BACKGROUND

Optical detectors commonly use arrays of photodiodes in which each photodiode (or a row or column of such photodiodes in the array) is/are coupled to capacitors as a way to convert the charge produced by the respective photodiodes into voltages corresponding to the photons received by the respective photodiodes. These photodiode arrays are often referred to a charge-coupled devices or “CCDs”.

Because of the very large dynamic range of photon fluxes than can be encountered over various lighting conditions (e.g., twilight to midday sun), as used in imaging sensors CCD arrays are often subject to and expected to perform well over a photon fluxes differing by five or more orders or magnitude (logs). For example, at low lighting levels such as would be encountered at dusk or in a dimly lit room, a typical photon flux incident on a CCD array of a digital camera would be many orders of magnitude less than for the other end of the optical dynamic range, such as would be encountered under lighting conditions at midday in cloudless weather. Similar dynamic ranges for photon flux levels occur for optical sensors operating in non-visible wavelengths as well, e.g., ultraviolet (“UV”) and infrared (“IR”).

Saturation occurs for CCD arrays when an integration capacitor connected to the photodiode reaches full charge while the photocurrent is still increasing; any additional photocurrent is not accumulated in the integration capacitor, which can lead to a star pattern or other saturation effects such as so-called pixel blooming. Active Pixel Sensors (“APS”) and CMOS Image Sensors have also had the same or similar limiting dynamic range issues.

To address such saturation issues while under extreme flux environments, previous attempts at gain adjustment have been made. For example, traditionally the problem has been solved by using a two-channel approach. For scanners, a brute force method of custom low-gain and high gain-channels have been produced. For staring arrays, two channels have been created in the unit cell; one that integrates for a target integration time for low flux levels (corresponding to high-gain), and one that integrates for a significantly lower integration time for higher flux levels (low-gain).

Both of such traditional solutions for staring arrays and scanned arrays (scanners) require additional unit cell real estate and significant down stream signal processing. In these conventional solutions or techniques, both high-gain and low-gain channels are digitized and compared. Based on the output levels of both channels, a decision is made as to which channel to use. Then, a switch is activated to switch to the desired channel.

While prior art techniques have proven useful for their respective intended purposes, they can present difficulties or limitations with respect to complexity and cost. What is needed therefore are techniques that address optical sensor saturation problems while at the same time providing relatively simple circuit designs with commensurate costs.

### SUMMARY

The present disclosures provides methods, techniques, systems, and apparatus that address the limitations noted previously for prior art techniques. Automatic gain shifting (or switching, e.g., from one gain value or function to another) can be provided by utilizing a switch to selectively add or subtract an individual storage block or network of such storage blocks to a photodetector. Such aspects of the present disclosure can be applicable to MWIR as well as the entire EO spectrum, including but not limited to the UV, SWIR, MWIR, LWIR, and VLWIR.

One aspect of the present disclosure includes a photodetector and a switchable storage network including a storage element, in which the switchable storage network is configured and arranged to respond to a photocurrent from the photodetector and provide an increased storage for the circuit at a predetermined photocurrent. The storage elements can include one or more capacitors that can be coupled to integration capacitors of the photodetector. The switchable networks can include flux sensing switches such as MOSFETS that can activate at a desired or predetermined photocurrent level.

Further aspects of the present disclosure are directed to related methods, focal plane arrays and imaging systems.

Other features and advantages of the present disclosure will be understood upon reading and understanding the detailed description of exemplary embodiments, described herein, in conjunction with reference to the drawings.

### BRIEF DESCRIPTION OF DRAWINGS

Aspects of the disclosure may be more fully understood from the following description when read together with the accompanying drawings, which are to be regarded as illustrative in nature, and not as limiting. The drawings are not necessarily to scale, emphasis instead being placed on the principles of the disclosure. In the drawings:

FIG. 1 depicts a circuit diagram, in accordance with an embodiment of the present disclosure;

FIG. 2 depicts a graph of output voltage vs. photocurrent for of a circuit in accordance with an embodiment of the present disclosure;

FIG. 3 depicts a diagrammatic view of a focal plane array with automatic gain switching features, in accordance with an exemplary embodiment of the present disclosure;

FIG. 4 depicts a diagrammatic view of a generic optical system with a focal plane array with automatic gain switching, in accordance with exemplary embodiments of the present disclosure; and

FIG. 5 is a box diagram representing a method in accordance with an embodiment of the present disclosure.

One skilled in the art will appreciate that the embodiments depicted in the drawings are illustrative and that variations of those shown, as well as other embodiments described herein, may be envisioned and practiced within the scope of the present disclosure.

### DETAILED DESCRIPTION

Embodiments of the present disclosure are directed to devices, apparatus, systems and methods providing automatic gain switching for optical sensors or photodetectors. Such switching can be provided by utilizing a transistor, e.g., a MOSFET, as a switch to switch in or out one or more additional storage blocks, e.g., capacitors, for the optical sensor.

Embodiments of the present disclosure can provide an electronics circuit solution for electro-optical applications requiring very large instantaneous dynamic range while preserving sensitivity (maintaining high signal-to-noise ratio) at low flux levels. For example, for Medium Wave Infrared (MWIR) remote sensing, detecting many orders of magnitude of irradiance (photon flux) within the focal plane array (FPA) is desired. As was note previously, this has historically been a challenging problem due to FPA unit cell (pixel) constraints.

The present disclosure provides techniques utilizing a general purpose circuit that can be implemented in a form to provide very large instantaneous dynamic range for optical sensors, e.g., at the FPA unit cell level. Circuits according to the present disclosure can be used for or implemented with monolithic or hybrid types of FPAs. Circuits of the present disclosure can be implemented in various configurations, and can be used with any suitable type of preamplifier, as described in further detail below. Additionally, the circuits of the present disclosure can be utilized with or for any suitable clamp and/or sample and hold circuits used for FPAs.

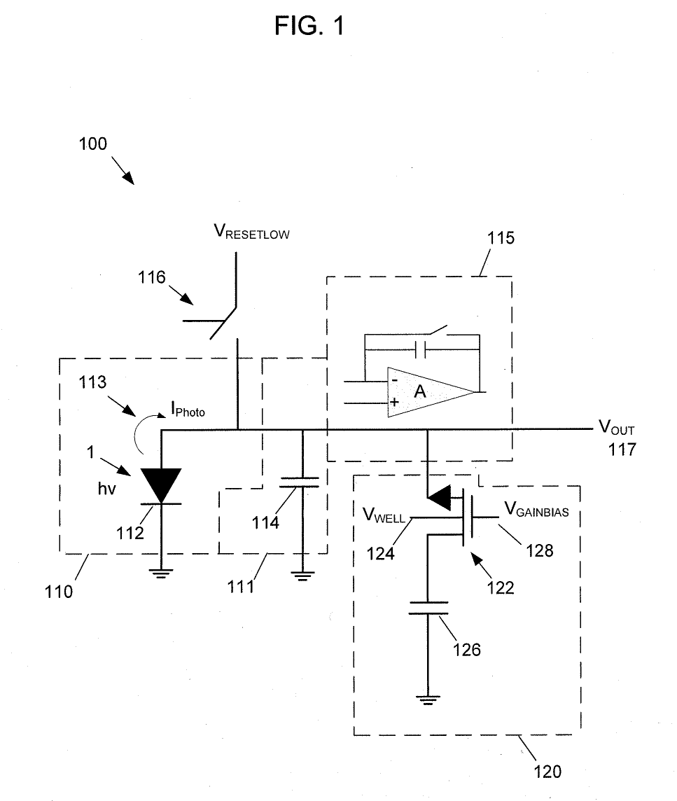

FIG. 1 depicts a circuit diagram of a circuit 100, in accordance with an exemplary embodiment of the present disclosure, including a photodetector section, e.g., a photodetector unit cell of an FPA, 110 and a switched storage block or storage network section 120. Photodetector section 110 can include a photodiode 112. Photodiode 112 can be (but is not necessarily) connected to an integration capacitor 114 and reset switch 116. Switched storage network 120 can include a switch 122, e.g., n-MOSFET, and a storage block 126, e.g., a second capacitor or capacitor network. Circuit 100 can include preamplifier section, denoted by 111 and can include optional additional preamplifier elements as denoted by circuit section 115 with optional representative capacitive transimpedance amplifier (“CTIA”) architecture shown.

In operation of circuit 100, switch 122 functions as a flux sensing switch. As a photon flux 1 (with photon energy, hv, indicated) impinges upon photodiode 112, a corresponding photocurrent 113 is produced. The photocurrent 113 accumulates in integration capacitor 114. The preamplifier circuit 111 is configured such that, at low flux levels, a small integration capacitor 114 is used for high Signal-to-Noise Ratio (low noise). At higher flux levels, the flux sensing switch 122 activates (e.g., turns off) and an additional storage block/element (e.g., second capacitor 126) is automatically switched in to (i) alter the gain (e.g., charge over capacitance) of the circuit 100, and (ii) map the rest of the desired dynamic range for the optical sensor 112. If desired, the circuit 100 can be implemented with additional switches and capacitors forming one or more additional switched storage network 120 so that the circuit 100 operates to switch in more capacitance as needed for operation over a desired dynamic range.

In exemplary embodiments, switch 122 is a MOSFET, e.g., an n-MOSFET. The bulk of the MOSFET is connected to the substrate. The movement of the bulk-to-source potential is advantageously used to trigger the switching (either on or off) of the transistor and thereby connect or disconnect the additional storage elements as needed for the flux conditions present on the photosensor, e.g., photodiode 112. A MOSFET used as switch 122 can thus provide automatic switching and connection to the additional storage element(s) based on a changing differential between the output voltage 117 of the circuit and the bulk-to-source voltage: Δ(V_{OUT}−V_{BS}), indicated in FIG. 1 by V_{OUT} 117-V_{WELL} 124.

With continued reference to FIG. 1, for exemplary embodiments including a CTIA preamplifier configuration, as shown in the additional preamplifier elements circuit section 115, a network of one or more integration capacitors can be automatically switched in and out depending on the incoming flux level (which produces a corresponding photocurrent in the photodiode or photodiodes). The automatic switching mechanism is a switch (transistor) placed between the capacitor feedback node and the CTIA output. The bulk of the transistor is connected to substrate, and as the output of the CTIA integrates downward, the Bulk to Source potential (V_{BS}) of the switch increases. While the V_{BS}, of the switch increases, the threshold voltage of the switch increases. Eventually, due to the movement V_{BS}, the switch 122 will alter state, e.g., turn off.

Further illustrating the general applicability of circuits of the present disclosure to different optical sensor preamplifier designs, in embodiments where preamplifier 115 is configured as a source follower with detector 112 (as a source follower per detector, or “SFD”), at the beginning of frame/line integration, the SFD will be high gain mode set by integration capacitor 114. At a particular flux level, determined by V_{GAINBIAS} and the semiconductor process, transistor 122 will turn on (as opposed to off in the CTIA previously described) as a result of the difference in the bulk-to-source potential and V_{OUT}. The SFD will then be in low gain mode set by capacitors 114 and 126.

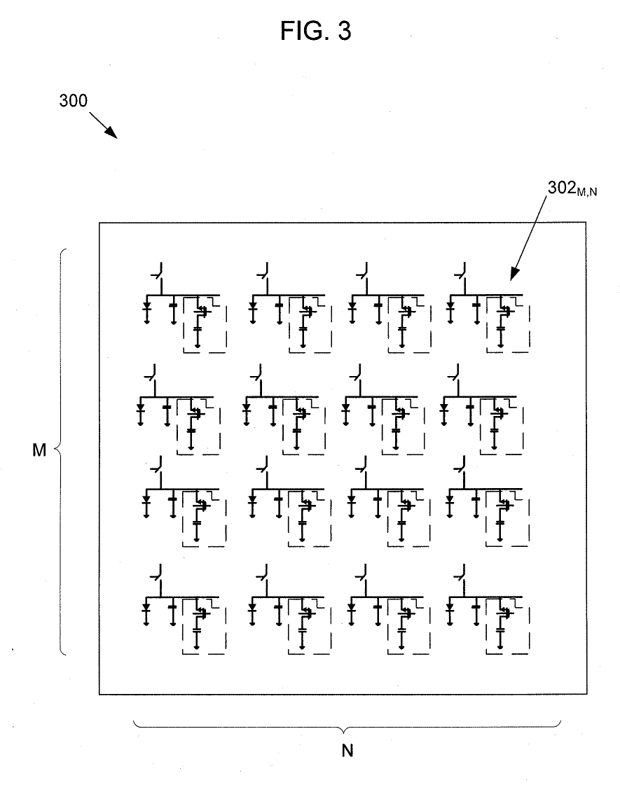

With continued reference to FIG. 1, exemplary embodiments of circuit 100 can be implemented on a substrate utilizing a deep sub-micron process, e.g., 0.35 micron for IR detectors, and a 0.18 micron process for visible detectors, such as made commercially available by JAZZ Semiconductor. As described in further detail for FIG. 3, infra, exemplary embodiments include an array of unit cells of detectors and switchable storage circuits implemented on a suitable substrate.

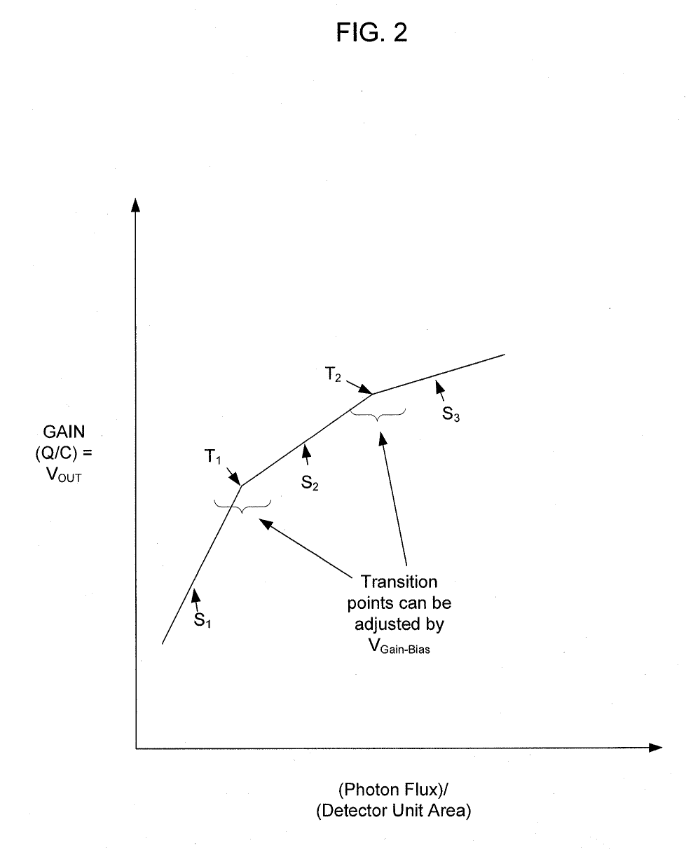

FIG. 2 depicts a graph 200 of output voltage vs. photocurrent for of a circuit in accordance with an embodiment of the present disclosure. As shown, at low flux levels, higher gain is provided, as indicated by steeper slope S₁. This corresponds to the use of a small integration capacitor (capacitance) used for high SNR and low noise. At higher photon flux levels, the flux sensing switch (e.g., as formed by MOSFET shown in FIG. 1) changes state (e.g., turns off) and additional capacitance is automatically switched in to the circuit to map the rest of the dynamic range.

In FIG. 2, slopes S₂ and S₃ correspond to the switching in of additional capacitors (of desired capacitance) to handle higher optical flux levels. FIG. 2 also indicates transition points T₁ and T₂ between slopes S₁-S₃. Transition points T₁ and T₂, corresponding to when the transition or shift between different gain regimes can be selected, e.g., by adjusting the V_{GAINBIAS} 128 to MOSFET 122 in FIG. 1.

As described previously, a switch (e.g., switching transistor) and storage (capacitive) network, e.g., circuit portion 120 in FIG. 1, can be implemented in many different types of configurations and with many different suitable types of preamplifier sections to provide large dynamic gain to optical detectors, e.g., FPAs. Certain non-exhaustive examples of suitable direct injection (“DI”) configuration preamplifier sections/circuits, in which embodiments of the present disclosure can be implemented with or adapted to, are disclosed in U.S. Pat. No. 4,093,872 and U.S. Pat. No. 5,382,977; the entire contents of both of which are incorporated herein by reference. As used herein, the term “DI” is also intended to refer to suitable feedback-enhanced direct injection (“FEDI”) circuits such as those disclosed in U.S. Pat. No. 6,133,596, the entire contents of which are incorporated herein by reference. Certain non-exhaustive suitable source follower (“SF”) configurations in which embodiments of the present disclosure can be implemented with or adapted to are disclosed in U.S. Pat. No. 4,445,117 and U.S. Pat. No. 5,083,016; the entire contents of both of which are incorporated herein by reference. Certain non-exhaustive examples of suitable CTIA configurations for use with or adaptation for embodiments of the present disclosure are disclosed in U.S. Pat. No. 4,978,872, the entire content of which is incorporated herein by reference. Further suitable preamplifier circuit configurations useful for implementation with circuits of the present disclosure include those disclosed in Dakin, et al, Handbook of Optoelectronics, Taylor & Francis, Inc., Vol. 1 (2006) (see, e.g., pages 112-114); the entire contents of which are incorporated herein by reference.

FIG. 3 depicts a diagrammatic view of a focal plane array 300 with automatic gain switching features, in accordance with an exemplary embodiment of the present disclosure. As shown, FPA 300 can include a desired number (M×N) of unit cells 302 including photodetectors and automatic gain switching, e.g., circuit sections 110 and 120 of shown and previously described for FIG. 1. FPAs according to the present disclosure can be implemented with any suitable optical systems. The FPA can include suitable readout integrated circuitry, or “ROIC,” and can be either of a monolithic or hybrid design.

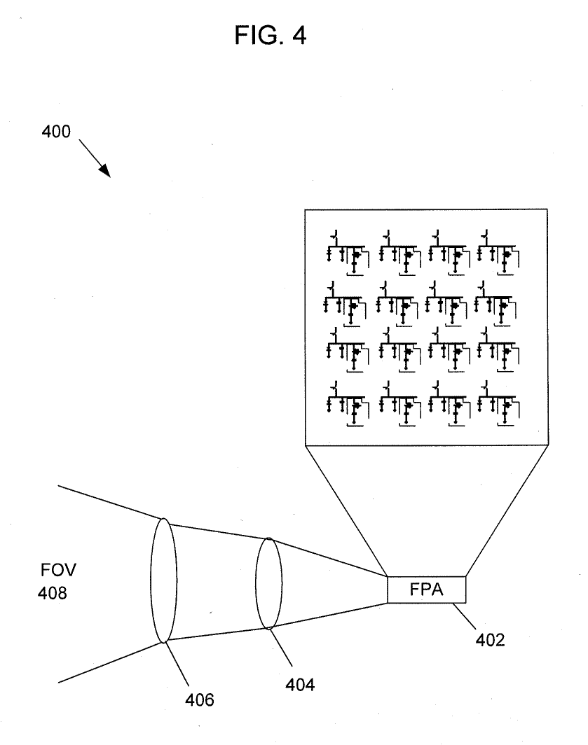

FIG. 4 depicts a diagrammatic view of a generic optical system 400 with a focal plane array with automatic gain switching, in accordance with exemplary embodiments of the present disclosure. System 400 includes FPA 402, configured and arranged at the focal plane of lens 404. One or more additional lens 406 can be implemented with lens 404 as part of an optical system having desired optical performance characteristics, e.g., focal length, field of view 408 (“FOV”) size, operational wavelength(s), lens material, etc. In exemplary embodiments, optical system 400 can be implemented as an electrooptic imager operational at or over a desired wavelength range, e.g., near infrared (“NIR”) or MWIR, etc.

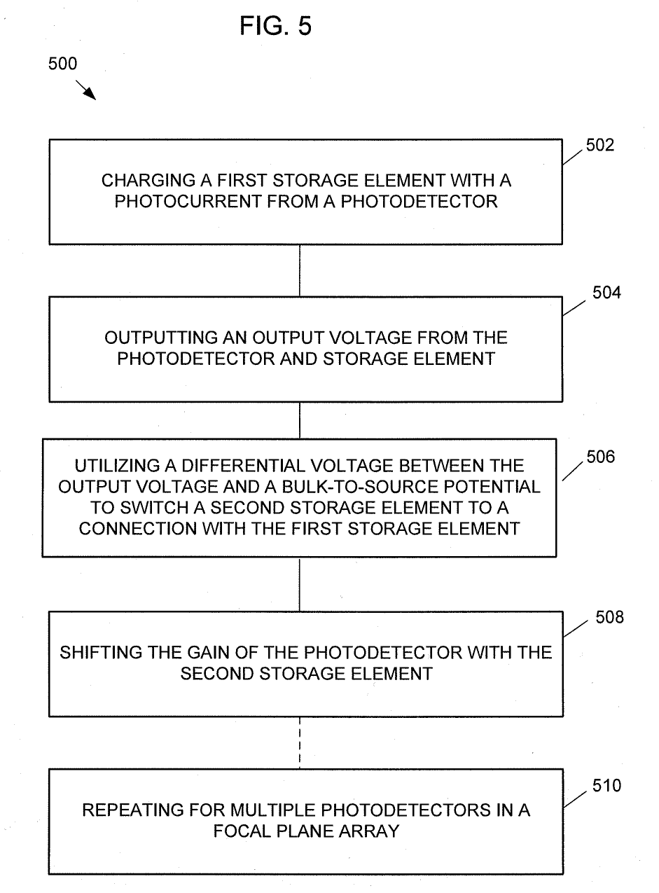

FIG. 5 is a box diagram representing a method 500 in accordance with an embodiment of the present disclosure. A first capacitor can be charged with a photocurrent from a photodetector, as described at 502. A capacitor output voltage can be outputted based on the charge of the first capacitor, as described at 504. A differential voltage between the capacitor output voltage and a bulk-to-source voltage can be utilized to switch a second capacitor to a parallel connection with the first capacitor, as described at 506.

Continuing with the description of method 500, the gain of the photodetector can be shifted with the second capacitor, as described at 508. The method 500 can be repeated for multiple photodetectors in a FPA, as described at 510, such as FPA 300 shown and described for FIG. 3.

Advantages: thus, embodiments of the present disclosure/invention, can provide a compact solution to saturation and the need to accommodate large optical flux dynamic ranges. Embodiments of the present invention do not require downstream signal processing. Hence, they can be more compact, lower power, and ease system implementation and integration.

Accordingly, compared to the existing technologies, embodiments of the present disclosure can provide the advantage of automatically providing large dynamic ranges for optical sensors. Techniques and apparatus of the present disclosure can be much simpler and easier to implement in integrated circuits than prior art techniques. Systems according to the present disclosure can be compact and do not require downstream signal processing Systems of the present disclosure, which can be disposable, can be relatively inexpensive.

While certain embodiments have been described herein, it will be understood by one skilled in the art that the methods, systems, and apparatus of the present disclosure may be embodied in other specific forms without departing from the spirit thereof. For example, while storage elements/blocks have been described in the context or one or more capacitors specifically, others may be used within the scope of the present disclosure. For example, a storage element could alternatively be implemented as a register or a series of MOSFETs.

Accordingly, the embodiments described herein are to be considered in all respects as illustrative of the present disclosure and not restrictive.

What is claimed:

1. A gain switching circuit comprising:
a photodetector; and
a switchable storage network including a storage element, wherein the switchable storage network is configured and arranged to respond to a photocurrent from the photodetector and provide an increased storage for the circuit at a predetermined photocurrent.

2. The circuit of claim 1, wherein the storage element comprises a transistor switch configured and arranged to connect the storage element to the photodetector at a desired photocurrent.

3. The circuit of claim 2, wherein the transistor switch comprises a MOSFET, wherein the MOSFET is configured to switch off at predetermined differential voltage between an output voltage of the photo detector and a bulk-to-source potential of the MOSFET.

4. The circuit of claim 1, wherein the storage element comprises one or more capacitors.

5. The circuit of claim 1, wherein the storage element comprises one or more registers.

6. The circuit of claim 2, wherein the transistor switch comprises a plurality of transistor switches.

7. The circuit of claim 1, wherein the photodetector comprises a photodiode.

8. The circuit of claim 1, further comprising a preamplifier section connected to the photodetector.

9. The circuit of claim 8, wherein the preamplifier section comprises a source follower preamplifier.

10. The circuit of claim 8, wherein the preamplifier section comprises a direct injection preamplifier.

11. The circuit of claim 8, wherein the preamplifier section comprises a CTIA preamplifier.

12. The circuit of claim 8, wherein the preamplifier section comprises a SFD preamplifier.

13. The circuit of claim 8, wherein the preamplifier section comprises a DI preamplifier.

14. The circuit of claim 8, wherein the preamplifier section comprises a FEDI preamplifier.

15. The circuit of claim 8, wherein the preamplifier section comprises a current mirror preamplifier.

16. The circuit of claim 8, wherein the preamplifier section comprises a Resistor Transimpedance Amplifier.

17. A method of providing multiple gain values for a photodetector circuit, the method comprising:
charging a first storage element with a photocurrent from a first photodetector;
outputting an output voltage from the first photodetector and the first storage element;
utilizing a differential voltage between the output voltage and a bulk-to-source potential to switch a second storage element to a connection with the first storage element; and
shifting the gain of the first photodetector with the second storage element.

18. The method of claim 17, wherein the first storage element comprises an integration capacitor.

19. The method of claim 17, wherein the photodetector comprises a photodiode.

20. The method of claim 17, wherein the second storage element comprises a register.

21. The method of claim 20, wherein the register comprise a linked series of MOSFETs.

22. The method of claim 17, further comprising charging a third storage element with a photocurrent from a second photodetector of an M×N array:
outputting an output voltage from the second photodetector and the third storage element;
utilizing a differential voltage between the output voltage and a bulk-to-source potential to switch a fourth storage element to a connection with the third storage element; and
shifting the gain of the second photodetector with the fourth storage element.

23. The method of claim 17, further comprising adjusting the transition from a first gain of the circuit to a second gain of the circuit by adjusting a gain-bias voltage of a MOSFET connected to the second storage element.

24. A focal plane array with automatic gain shifting, the array comprising:
a plurality of unit cells configured in an M×N array, each unit cell including a photodetector; and a switchable storage network including a storage element, wherein the switchable storage network is configured and arranged to respond to a photocurrent from the photodetector and provide an increased storage for the circuit at a predetermined photocurrent; and wherein the plurality of unit cells are disposed on a common substrate.

25. The focal plane of claim 24, wherein the photodetector of each unit cell is coupled to an integration capacitor, and wherein the storage element of each switchable network comprises a second capacitor of desired value.

26. The focal plane of claim 24, wherein each unit cell comprises a preamplifier.

27. The focal plane of claim 26, wherein the preamplifier comprises a source follower preamplifier.

28. The focal plane of claim 26, wherein the preamplifier comprises a CTIA preamplifier.

29. The focal plane of claim 26, wherein the preamplifier comprises a source follower preamplifier.

30. The focal plane of claim 26, wherein the preamplifier section comprises a DI preamplifier.

31. The focal plane of claim 26, wherein the preamplifier section comprises a FEDI preamplifier.

32. The focal plane of claim 26, wherein the preamplifier section comprises a current mirror preamplifier.

33. The focal plane of claim 26, wherein the preamplifier section comprises a Resistor Transimpedance Amplifier.

34. An imaging system with automatic gain shifting, the system comprising:
a focal plane array including a plurality of unit cells configured in an M×N array, each unit cell including a photodetector; and a switchable storage network including a storage element, wherein the switchable storage network is configured and arranged to respond to a photocurrent from the photodetector and provide an increased storage for the circuit at a predetermined photocurrent; and wherein the plurality of unit cells are disposed on a common substrate, the focal plane array further comprising ROIC circuitry configured and arranged to produce an output; and
one or more optical elements configured and arranged to project a field of view onto the focal plane array.

35. The imaging system of claim 34, wherein the optical elements are configured and arranged to project an infrared image onto the focal plane array.

36. The imaging system of claim 35, wherein the optical elements are configured and arranged to project a MWIR image onto the focal plane array.
